(19) United States
(12) Patent Application Publication
(10) Pub. No.: US 2014/0305487 A1
(43) Pub. Date: Oct. 16, 2014

(54) SOLAR CELL APPARATUS

(71) Applicant: LG INNOTEK CO., LTD., Seoul (KR)

(72) Inventors: Se Han Kwon, Seoul (KR); Do Won Bae, Seoul (KR)

(21) Appl. No.: 14/357,453

(22) PCT Filed: Nov. 8, 2012
(86) PCT No.: PCT/KR2012/009426

§ 371 Date: May 9, 2014

(30) Foreign Application Priority Data
Nov. 9, 2011 (KR) 10-2011-0116437

(51) Int. Cl. H01L 31/042

(52) U.S. Cl. CPC H01L 31/0422
USPC 136/244

(57) ABSTRACT

Disclosed is a solar cell apparatus. The solar cell apparatus includes a support substrate supporting a plurality of solar cells, a hole formed through a portion of the support substrate, an insulator filled in the hole, and a bus bar connected to the solar cells and passing through the insulator.

### TECHNICAL FIELD

The embodiment relates to a solar cell apparatus.

### BACKGROUND ART

A solar cell (or photovoltaic cell) is a core element in solar power generation to directly convert solar light into electricity.

For example, if the solar light having energy greater than band-gap energy of a semi-conductor is incident into a solar cell having the PN junction structure, electron-hole pairs are generated. As electrons and holes are collected into an N layer and a P layer, respectively, due to the electric field formed in a PN junction part, photovoltage is generated between the N and P layers. In this case, if a load is connected to electrodes provided at both ends of the solar cell, current flows through the solar cell.

Recently, as energy consumption is increased, solar cells to convert the solar light into electrical energy have been developed.

In particular, a CIGS-based solar cell, which is a PN hetero junction apparatus having a substrate structure including a glass substrate, a metallic back electrode layer, a P type CIGS-based light absorbing layer, a high resistance buffer layer, and an N type window layer, has been extensively used.

Various studies and researches have been performed to improve electrical characteristics of the solar cell, such as low resistance and high transmittance.

Current generated from the solar cell is applied to a junction box through bus bars. In general, in order to connect the bus bars formed on the top surface of the solar cell panel to the junction box, holes having positive and negative polarities are formed in a solar cell substrate, so the solar cell substrate may be damaged due to the cracks between the holes.

### DISCLOSURE OF INVENTION

### Technical Problem

The embodiment provides a solar cell apparatus capable of preventing a support substrate from being damaged, reducing the failure rate in the subsequent process, and improving productivity by reducing the number of holes formed in the support substrate.

### Solution to Problem

According to the embodiment, there is provided a solar cell apparatus including a support substrate supporting a plurality of solar cells, a hole formed through a portion of the support substrate, an insulator filled in the hole, and a bus bar connected to the solar cells and passing through the insulator.

### Advantageous Effects of Invention

As described above, according to the solar cell apparatus of the embodiment, one hole is formed in the support substrate, and an insulator is inserted into the hole. Accordingly, the process of forming the hole can be reduced, so that the productivity can be improved.

In addition, the failure rate, which may occur in the subsequent process after a plurality of holes are formed in the support substrate, can be reduced.

### BRIEF DESCRIPTION OF DRAWINGS

FIG. 1 is an exploded perspective view showing a solar cell module according to the embodiment;

FIG. 2 is a plan view showing the solar cell module according to the embodiment; and

FIG. 3 is a sectional view taken along line A-A of FIG. 2.

### BEST MODE FOR CARRYING OUT THE INVENTION

In the description of the embodiments, it will be understood that when a substrate, a layer, a film or an electrode is referred to as being on or under another substrate, another layer, another film or another electrode, it can be directly or indirectly on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

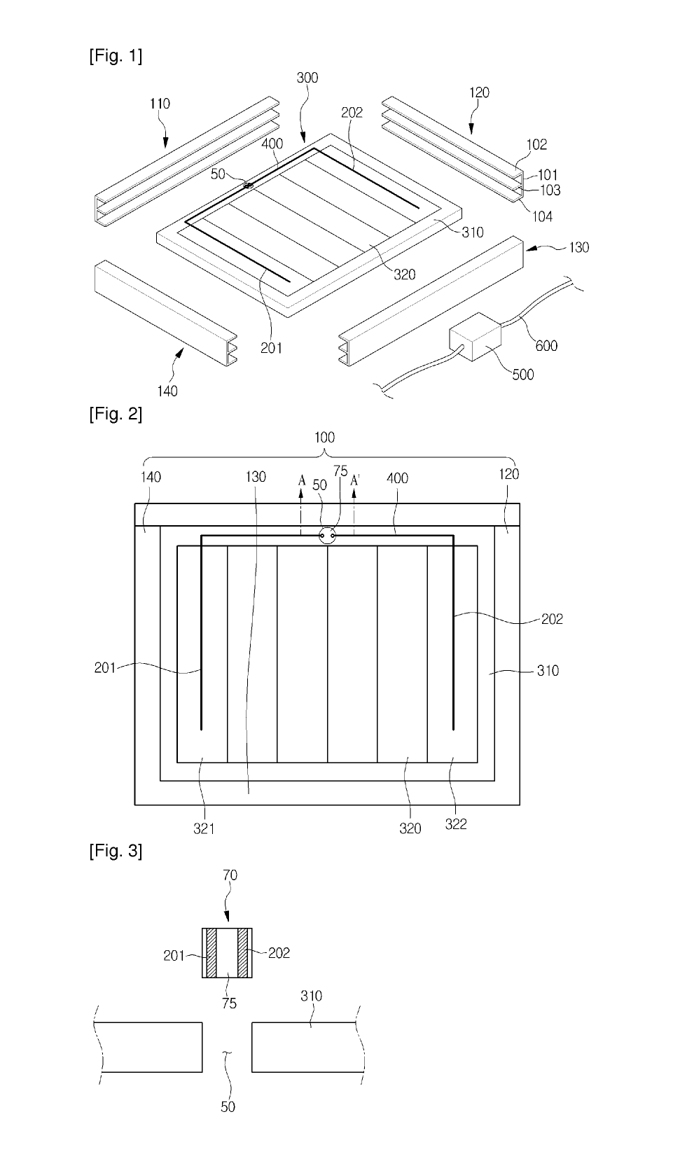

FIG. 1 is an exploded perspective view showing a solar cell module according to the embodiment. FIG. 2 is a plan view showing a solar cell module according to the embodiment. FIG. 3 is a sectional taken along line A-A of FIG. 2.

Referring to FIGS. 1 to 3, the solar cell module according to the embodiment includes a solar cell panel 300, a hole formed at one side of the solar cell panel 300, an insulator filling a portion of the hole 50, and a bus bar 400 formed at a portion of the hole 50.

The frame 100 receives the solar cell panel 300. In more detail, the frame 100 surrounds the lateral side of the solar cell panel 300. For example, the frame 100 is provided at four lateral sides of the solar cell panel 300.

The frame 100 may include a metallic material such as aluminum and a polymer resin. The frame 100 includes first to fourth sub-frames 110, 120, 130, and 140. The first to fourth sub-frames 110 to 14 may be coupled with each other, or may integrally formed with each other.

The first sub-frame 110 surrounds one lateral side of the solar cell panel 300. The second sub-frame 120 receives another lateral side of the solar cell panel 300. The third sub-frame 130 faces the first sub-frame 110 while interposing the solar cell panel 300 therebetween. The third sub-frame 130 receives still another lateral side of the solar cell panel 300. The fourth sub-frame 140 receives still another lateral side of the solar cell panel 300. The fourth sub-frame 140 faces the second sub-frame 120 while interposing the solar cell panel 300 therebetween.

The first sub-frame 110, the second sub-frame 120, and the fourth sub-frame 140 have structures similar to each other. In other words, the first to fourth sub-frames include support parts to receive the solar cell panel 300.

For example, the first sub-frame 110, the second sub-frame 120, and the fourth sub-frame 140 include a first support part 101, a second support part 102, a third support part 103, and a fourth support part 104.

The first support part 101 is provided at the lateral side of the solar cell panel 300. The first support part 101 supports the lateral side of the solar cell panel 300.

The second support part 102 extends from the first support part 101 so that the second support part 102 is provided on the top surface of the solar cell panel 300. The second support part 102 supports the top surface of the solar cell panel 300. The third support part 103 extends from the first support part 101 so that the third support part 103 is provided on the bottom surface of the solar cell panel 300. The third support part 103 supports the bottom surface of the solar cell panel 300. The fourth support part 104 extends from the first support part 101 so that the fourth support part 104 is provided under the third support part 103. The first to fourth support parts 101 to 104 are integrally formed with each other.

The solar cell panel 300 has a plate shape. For example, the solar cell panel 300 may have the shape of a rectangular plate shape. The solar cell panel 300 is provided inside the frame 100. In more detail, the outer portion of the solar cell panel 300 is provided inside the frame. In other words, the four lateral sides of the solar cell panel 300 are provided inside the frame 100. The solar cell panel 300 converts the incident solar light into electric energy. The solar cell panel 300 includes a support substrate 310 and a plurality of solar cells 320.

In addition, although not shown in drawings, a sealing member (not shown) is interposed between the solar cell panel 300 and the frame 100. The sealing member may include resin having elasticity. The sealing member prevents impurities from being infiltrated between the solar cell panel 300 and the frame 100. In addition, the solar cell module according to the embodiment includes protective glass and ethylene vinylene acetate (EVA).

The protective glass is provided on the solar cells 320. The protective glass protects the solar cells 320 from external physical shock and/or foreign matters. The protective glass is transparent. For example, the protective glass may include tempered glass.

The EVA film is interposed between the protective glass and the solar cells 320. The EVA film serves as a buffer function between the protective glass and the solar cells 320.

The bus bar 400 is connected to the solar cell panel 300. In more detail, the bus bar 400 is provided on the top surface of the outermost solar cell 320. The bus bar 400 directly makes contact with the top surface of the outermost solar cells 320 so that the bus bar 400 is connected to the solar cells 400.

The support substrate 310 is provided at a portion thereof with the hole 50 so that the bus bar 400 may be connected to the cable 600 through the hole 50.

The bus bar 400 includes a positive electrode 201 and a negative electrode 202. If holes are formed for the positive electrode 201 and the negative electrode 202 for the purpose of connection with the junction box 500, drilling is performed through a laser scheme or a mechanical scheme, so cracks occur between holes 50, so that the support substrate 310 may be damaged.

According to the embodiment, one hole 50 is formed, so that the above problem may be overcome. In detail, a single hole 50 is formed at a portion of the support substrate 310 so that the single hole 50 has a diameter sufficient to receive the bus bar 400.

For the illustrative purpose, the insulator 75 separated from the hole 50 is shown in FIG. 3. According to the embodiment of the disclosure, a connection part 70 may include the insulator 75 to fill the hole 50 and the bus bars 400 including the positive electrode 201 and the negative electrode 202 while separately passing through the insulator 75

Next, the insulator 75 having a diameter corresponding to the hole 50 is provided in the hole 50, and the bus bars 400 including the positive electrode 201 and the negative electrode 202 are inserted into portions of the insulator 75 while being spaced apart from each other.

The solar cells 320 are provided inside the support substrate 310, and the hole 50 may be provided outside the support substrate 310.

According to the embodiment, the single hole 50 is formed, and the bus bars 400 including the positive electrode 201 and the negative electrode 202 are inserted into the insulator 75 to be filled in the hole 50 while being spaced apart from each other. Accordingly, the support substrate 310 may be prevented from being damaged when the hole 50 is formed.

The insulator 75 may include a typical insulating material. In addition, the insulator 75 may include a material, such as polyethylene (PE), polyvinyl butyral (PVB), and isobutylene, for the insulating sheath around a wire, or a ceramic material which is a typical insulator.

After the insulator 75 has been filled in the hole 50, the bus bar 400 may be inserted into the hole 50. In addition, after the bus bar 400 has been inserted into the hole 50, the insulator 75 may be filled in the hole 50.

The junction box 500 is provided under the solar cell panel 300. The junction box 500 may be attached to the bottom surface of the solar cell panel 300. The junction box 500 may include a diode, and may receive a printed circuit board connected to the bus bar 400 and the cable 600.

In addition, the solar cell module according to the embodiment may further include a wiring connecting the bus bar 400 to the circuit board. The cable 600 is connected to the circuit board and connected to another solar cell panel 300.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a support substrate supporting a plurality of solar cells;
a hole formed through a portion of the support substrate;
an insulator filled in the hole; and
a bus bar connected to the solar cells while passing through the insulator.

2. The solar cell apparatus of claim 1, wherein the bus bar includes positive and negative electrodes provided on top surfaces of outermost solar cells, respectively.

3. The solar cell apparatus of claim 1, wherein the insulator includes at least one of polyethylene (PE), polyvinylbutyral (PVB), and isobutylene.

4. The solar cell apparatus of claim 1, wherein a number of the hole is singular.

5. The solar cell apparatus of claim 1, wherein the solar cells are provided inside the support substrate.

6. The solar cell apparatus of claim 1, wherein the hole is defined outside the support substrate.

7-15. (canceled)
